(19) United States
(12) Patent Application Publication
(10) Pub. No.: US 2014/0204661 A1
(43) Pub. Date: Jul. 24, 2014

(54) MEMORY WITH ELEMENTS HAVING TWO STACKED MAGNETIC TUNNELING JUNCTION (MTJ) DEVICES

(71) Applicants: Brian S. Doyle, Portland, OR (US); Arijit Raychowdhury, Hillsboro, OR (US); Yong Ju Lee, Sunnyvale, CA (US); Charles C. Kuo, Hillsboro, OR (US); Kaan Oguz, Dublin (IE); David L. Kencke, Beaverton, OR (US); Robert S. Chau, Beaverton, OR (US); Roksana Golizadeh Mojarad, San Jose, CA (US)

(72) Inventors: Brian S. Doyle, Portland, OR (US); Arijit Raychowdhury, Hillsboro, OR (US); Yong Ju Lee, Sunnyvale, CA (US); Charles C. Kuo, Hillsboro, OR (US); Kaan Oguz, Dublin (IE); David L. Kencke, Beaverton, OR (US); Robert S. Chau, Beaverton, OR (US); Roksana Golizadeh Mojarad, San Jose, CA (US)

(21) Appl. No.: 13/995,631

(22) PCT Filed: Dec. 22, 2011
(86) PCT No.: PCT/US11/66979

§ 371 Date: Jun. 19, 2013

(51) Int. Cl. H01L 43/02; G11C 11/16

(52) U.S. Cl. CPC H01L 43/02; G11C 11/1675
USPC 365/158; 257/295

(57) ABSTRACT

A magnetic memory having memory elements each with two magnetic tunneling junction (MTJ) devices is disclosed. The devices in each element are differentially programmed with complementary data. The devices for each element are stacked one above the other so that the element requires no more substrate area than a single MTJ device.

### FIELD OF THE INVENTION

The invention relates to the field of magnetic memories particularly those using magnetic tunneling junction (MTJ) devices.

### PRIOR ART AND RELATED ART

Among magnetic memories are those employing an MTJ device having a fixed or pinned layer and a free layer as described in “Current Switching in MgO-Based Magnetic Tunneling Junctions,” IEEE Transactions on Magnetics, Vol. 47, No. 1, January 2011 (beginning at page 156) by Zhu, et al. The direction of magnetization in the free layer is switched from one direction to another through spin torque transfer using a spin-polarized current. This direction determines whether an MTJ device is storing a 1 or a 0.

When the magnetic dipole moments of the free and fixed layer of an MTJ device are aligned (parallel to one another) the magnetic resistance (R_{P}) is lower than when the moments are opposite or anti-parallel (R_{AP}). Because the tunneling magnetic resonance ratio

$$\frac{RAP - RP}{RP}$$

is generally low, there are challenges in designing fast and reliable memories especially when taking into account process variations. One proposal for mitigating this is through the use of two MTJ devices that are differentially programmed. See, “Integrated Magnetic Memory for Embedded Computers Systems,” IEEEAC paper #1464, Version 3, Updated Oct. 20, 2006, by Hass et al.

### BRIEF DESCRIPTION OF THE DRAWINGS

FIG. 1A is a graph used to illustrate the timing difficulties in sensing the state of data stored in an MTJ device.

FIG. 1B is a graph used to illustrate that the timing difficulties of FIG. 1A are effectively eliminated when using the magnetic elements, each with two MTJ devices, as described below.

FIG. 2 is a cross-sectional, elevation view showing layers in an MTJ device.

FIG. 3 is a perspective view showing one embodiment of a memory element formed using two stacked MTJ devices and the element's connection to lines in a memory array.

FIG. 4 is an electrical schematic illustrating the electrical connections between the memory elements and their respective select transistors.

FIG. 5A is an electrical schematic used to describe the differential programming of complementary data into a memory element to achieve a first state.

FIG. 5B is an electrical schematic used to describe the differential programming of complementary data into a memory element to achieve a second state.

FIG. 6A is an electrical schematic used to show the sensing of data in a memory element when the memory element is programmed in a first state.

FIG. 6B is an electrical schematic used to show the sensing of data in a memory element when the memory element is programmed in a second state.

FIG. 7 is an alternate embodiment of the memory element where like regions in the MTJ devices face each other in a stacked arrangement.

FIG. 8 is an electrical schematic used to describe the operation of the memory element of FIG. 7.

FIG. 9 is a block diagram showing a computer system in which a memory as described below is used.

### DETAILED DESCRIPTION

A memory and its method of operation which employs magnetic tunneling junction (MTJ) devices is described. In the following description, numerous specific details are set forth such as specific layers in order to provide a thorough understanding of the present invention. It will be apparent to one skilled in the art, that the present invention may be practiced without these specific details. In other instances, well-known circuits and methods are not described in detail in order to avoid unnecessarily obscuring the present invention.

In FIG. 3 and other figures in this application, one or more memory elements and their associated select transistors are described. As will be appreciated, in practice many elements and transistors are simultaneously formed on a single substrate in a memory array. Moreover, other parts of a memory are formed at the same time, including sensing circuits and decoding circuits. Additionally, the MTJ layers of the memory elements may be deposited over an entire substrate or only in selected portions of the substrate where the elements are embedded in a larger structure.

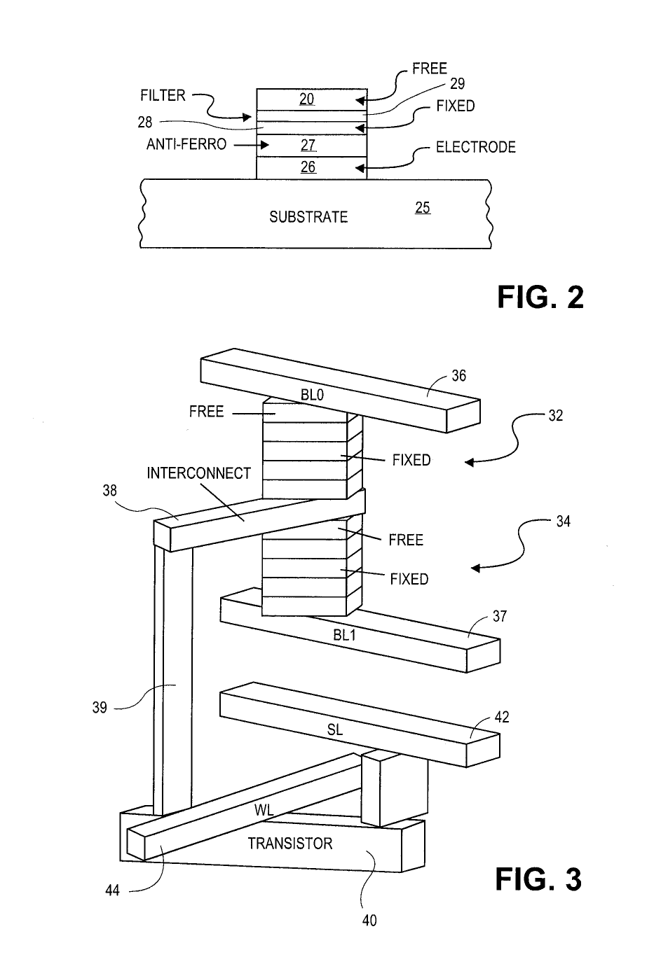

A typical design an MTJ device includes a bottom electrode 26 (FIG. 2) which itself may have several different metals such as ruthenium, copper nitride, titanium and tantalum, an anti-ferromagnetic layer 27, a fixed magnetic layer 28, pinned by the strength of layer 28, a filter layer 29 such as an MgO layer and a free magnetic layer 30. The specific number of layers, their composition and thicknesses are not critical to the present application.

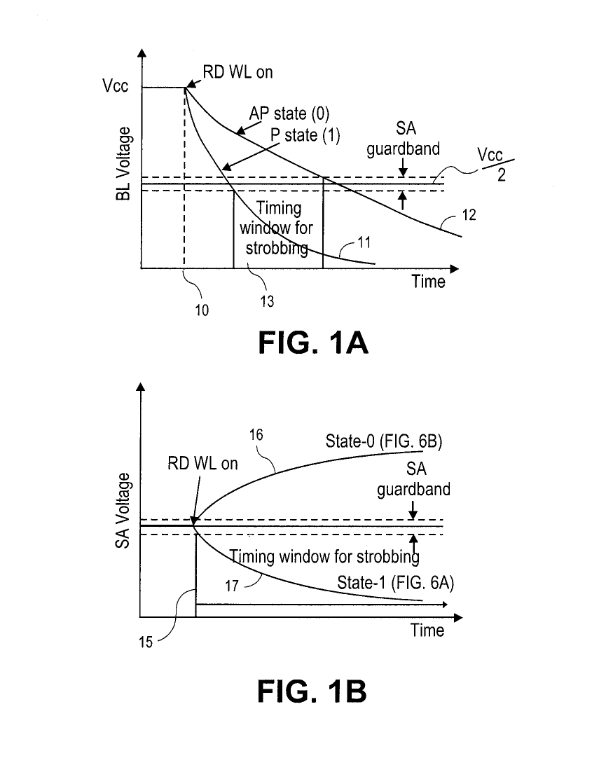

One problem in sensing the state (during a read cycle) of the device of FIG. 2 is illustrated in FIG. 1A. One terminal of the device is connected to a reference potential shown as V_{CC}. When the device is selected the potential on one terminal of a sense amp is a function of whether the device is programmed in one state or the other. In FIG. 1A, line 11 represents the decay that occurs when the device is in its lower resistance state (P state) while line 12 shows a slower rate representing the higher resistance state (AP state). This potential is compared to a reference potential such as

$$\frac{Vcc}{2}$$

applied to the second terminal of a sense amplifier.

Assume that at time 10 the device is selected, that is, the word line of the select transistor goes positive. The sense amplifier must be accurately strobed in order to determine the state of the device. Only during the window 13 can an accurate determination of the state of the device be determined. At the beginning of the window if the device is in the P state a potential of less than

$$\frac{Vcc}{2}$$

is present on the bit line. Similarly, if the device is in its AP state during the window 13, the bit line will be at a potential greater than

$$\frac{Vcc}{2}$$

thereby providing an accurate indication of the state. The simplified diagram of FIG. 1A does not take into account the variations in the MTJ devices that are typical. To compensate for these variations the guardband can be made larger but in so doing the timing window becomes more narrow making the strobing even more critical. As will be seen and described later, with the stacked MTJ devices the timing window is essentially open-ended. This provides for more reliable and faster reading.

The memory element of FIG. 3 has two MTJ devices such as shown in FIG. 2, one stacked upon the other. More specifically, device 32 is stacked on device 34. For this embodiment, the free layer of device 34 faces the fixed layer of device 32. The fixed layer of device 34 is coupled to bit line 1 (BL1) (37). The free layer of device 32 is coupled to BL0 (36). An interconnect 38 extends from between devices 32 and 34 and through the connecting structure 39 is coupled to one terminal of the transistor 40. The other terminal of the transistor 40 is connected to a sense line 42. The word line 44 provides a gate for the transistor 40 and thus where the source and drain regions of the transistor 40 are n-type regions, a positive potential on line 44 connects the interconnect structure 38 and 39 to the sense line 42. For the illustrated embodiment, devices 32 and 34 are in vertical alignment with one another. This is important since the memory element of FIG. 3 takes no more substrate area than the single MTJ device of FIG. 2.

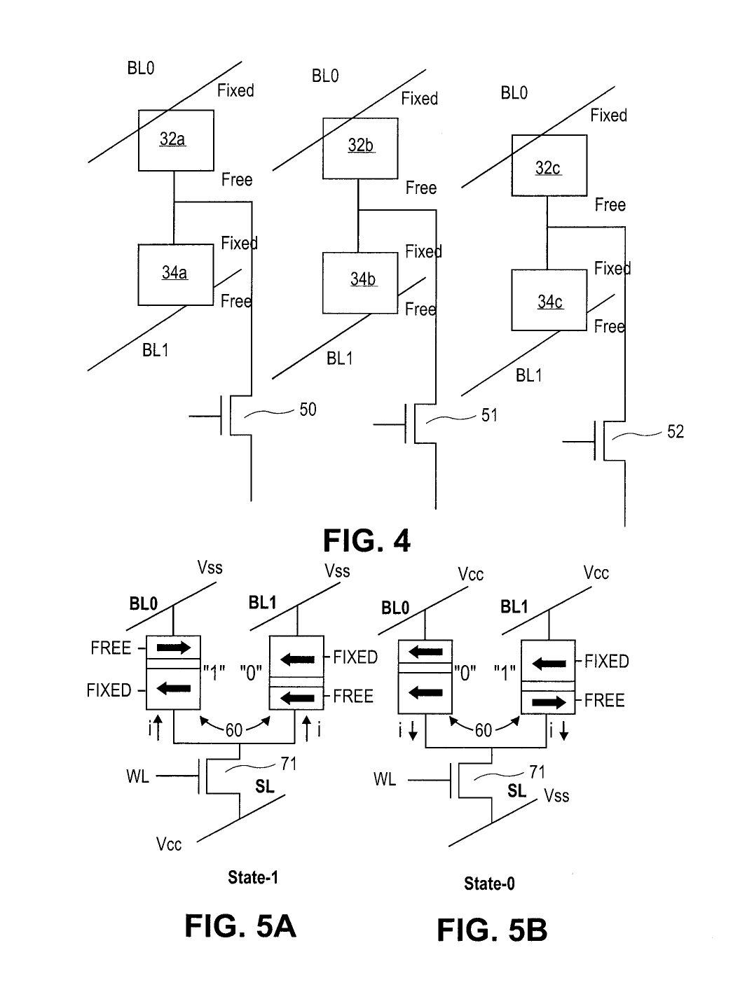

In FIG. 4, three memory elements such as shown in FIG. 3 have been redrawn to show how they may be arranged in a memory array. One memory element is shown as having devices 32a and 34a coupled to a select transistor 50. Another has devices 32b and 34b and are coupled to a select transistor 51. Lastly, one of the memory elements has device 32c and 34c coupled to a select transistor 52. Each of the memory devices is connected to a different pair of bit lines, BL1 and BL0. A common word line may connect the gates of the transistors 50, 51 and 52, depending on the configuration of the memory array.

The memory element of FIG. 3 has been redrawn in FIGS. 5A and 5B with the devices separated to better describe how programming occurs. Assume that the memory element is to be programmed with a first state (State 1). To program the element both bit lines are coupled to V_{SS} and the sense line is coupled to V_{CC}. When a potential is applied to the word line, current flows from the sense line to the bit lines BL0 and BL1. (The potential applied to the word line may be boosted above V_{CC} to eliminate threshold voltage drop across the select transistor.) Since the current in one device flows from the free layer to the fixed layer and in the other device from the fixed layer to the free layer, the devices will be differentially programmed. Note, the input data to be programmed into the element determines the voltage on BL0 and BL1 and the voltage on the sense line.

In FIG. 5B the opposite state is programmed into the memory element. Here, BL0 and BL1 are coupled to V_{CC} and the sense line is coupled to V_{SS}. The current now flows downward through the devices and therefore the device on the left is programmed with a 0 while the device on the right is programmed with a 1. Once again, the data to be written into the memory element determines the potentials that are applied by BL0, BL1 and the sense line.

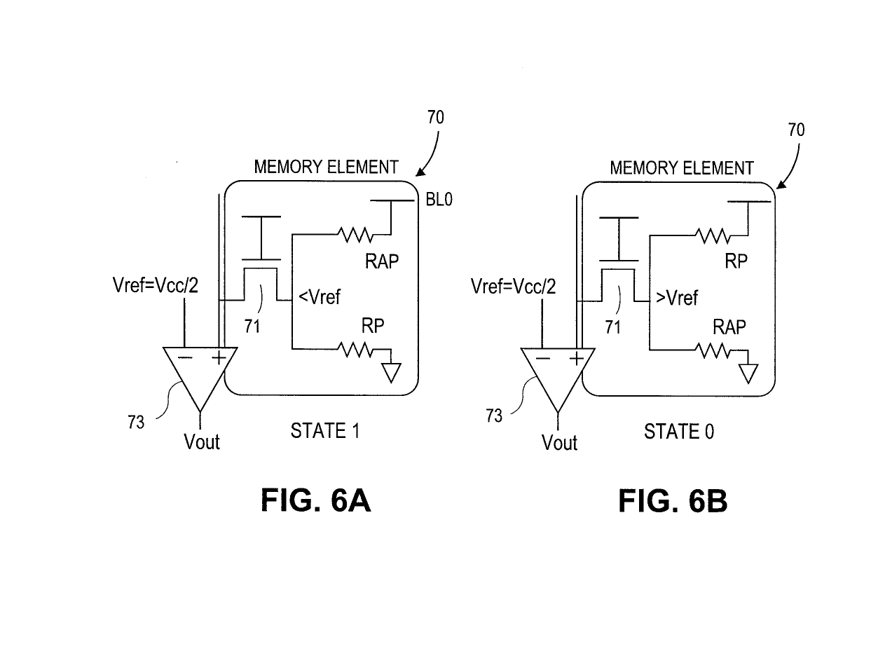

Referring to FIG. 6A, the memory element of FIG. 5A has been drawn in a schematic form to explain how data is read from the element. The resistances associated with the element of FIG. 5A are shown in FIG. 6A as R_{AP} (higher resistance) and R_{P} (lower resistance). One terminal of one MTJ device, represented by R_{AP} is connected to V_{SS} (BL0). One terminal of the other device represented as R_{P} is connected to ground (BL1). The common terminal between the two devices is coupled through the select transistor 71 to one terminal of a sense amp 73. The other terminal of the sense amp receives a reference potential such as

$$\frac{Vcc}{2} .$$

The resistances R_{AP} and R_{P} form a voltage divider and since R_{AP} has higher resistance than R_{P}, the select transistor couples a potential less than

$$\frac{Vcc}{2}$$

to the positive terminal of the sense amp. The output of the sense amp provides a potential which reflects the state of the memory element. It should be noted that the sense amp 73 has a high input impedance and thus the current flowing through the devices forming the memory element of FIG. 6A is less than that needed to program the devices. Note that in FIG. 5A the MTJ devices are coupled in parallel between V_{CC} and V_{SS}. In contrast in FIG. 6A, V_{CC} is applied to the series connected devices; because the input impedance of the sense amp is high no substantial current flows into the sense amp.

The memory element 70 of FIG. 6B corresponds to the programmed memory element of FIG. 5B. Once again, the common terminal between the devices is coupled through the select transistor 71 to the high impedance input of the sense amp 73. Here however, R_{P} (the lower resistance) is coupled to the V_{CC} and the higher resistance (R_{AP}) is coupled to ground. Therefore, the potential appearing at transistor 71 and coupled to the positive input terminal of the sense amp is greater than

$$\frac{Vcc}{2}$$

and the output of the sense amp 73 will be in an opposite state when compared to the output of the sense amp of FIG. 6A. Once again, the high input impedance of the sense amp prevents programming of the memory element, thus the differentially programmed devices of the memory element remain unchanged.

Referring to FIG. 1B, the timing advantage associated with having a differentially programmed memory element is illustrated by the curves 16 and 17. The line 17 represents the state of the memory element shown in FIG. 6A. Assume that at time 15 the word line is turned on and the sense line is at a potential of, for instance,

$$\frac{Vcc}{2} .$$

As soon as transistor 71 begins to conduct, the potential on the word line drops because R_{AP} is greater than R_{P}. Once the potential on the sense line drops below the guardband of the sense amplifier sensing can begin. Note sensing can occur at any time following time 15 after taking into account the guardband. Similarly, for the other state, represented by line 16 and the memory element of FIG. 6B, once transistor 71 begins to conduct, the word line rises in potential. Once it is above the guardband sensing can occur. The critical window 13 of FIG. 1A is not present and this makes reading of data from the memory element less critical and more reliable.

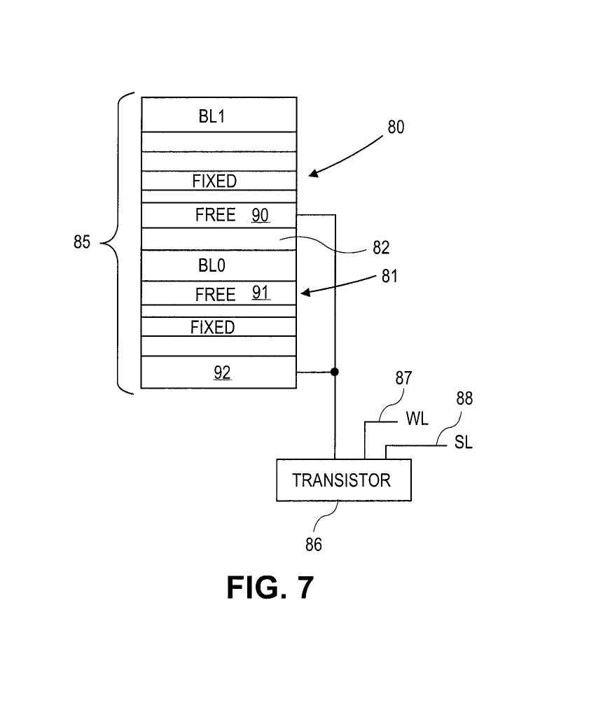

FIG. 7 illustrates an alternate stacking of the memory devices. The memory element 85 of FIG. 7 includes two MTJ devices of FIG. 2. Device 80 is stacked upon device 81. However, unlike FIG. 3, the free layer 90 of device 80 faces the free layer 91 of device 81. More specifically, there is no fixed layer between the free layers 90 and 91. With the arrangement of FIG. 7, the like regions of the MTJ devices may face one another although the layers in one device are insulated from the layers in the other device by an insulative layer 82.

In the arrangement of FIG. 7, the free layer 90 of device 80 is connected through the electrode 92 to the fixed layer of device 81. These layers are coupled to one of the terminals of the transistor 86. The other terminals of transistor 86 is coupled to the sense line 88. The gate of the transistor 87 forms a word line in a memory array. The fixed layer of device 80 is coupled to BL1 and the free layer of device 81 is coupled to BL0.

As was the case with the element of FIG. 3, all the layers of the memory element 85 are vertically aligned so that the substrate area of the memory element 85 requires no more substrate area than would be required by a single MTJ device. Also like the element of FIG. 3, each of the devices of the element 85 of FIG. 7 are differentially programmed with complementary data so that sensing of data occurs in a manner similar to that of FIG. 6A. Consequently the advantages of the timing discussed in conjunction with FIG. 1B are applicable.

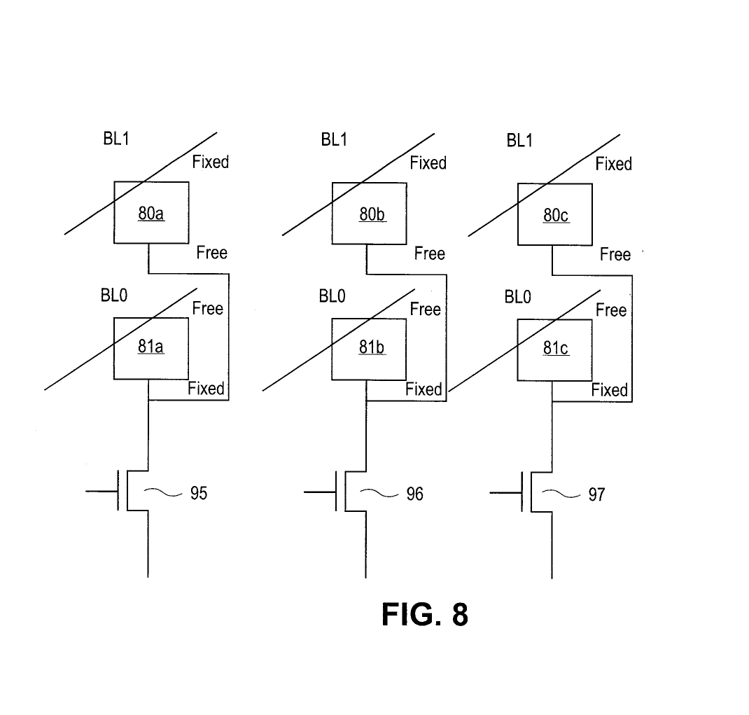

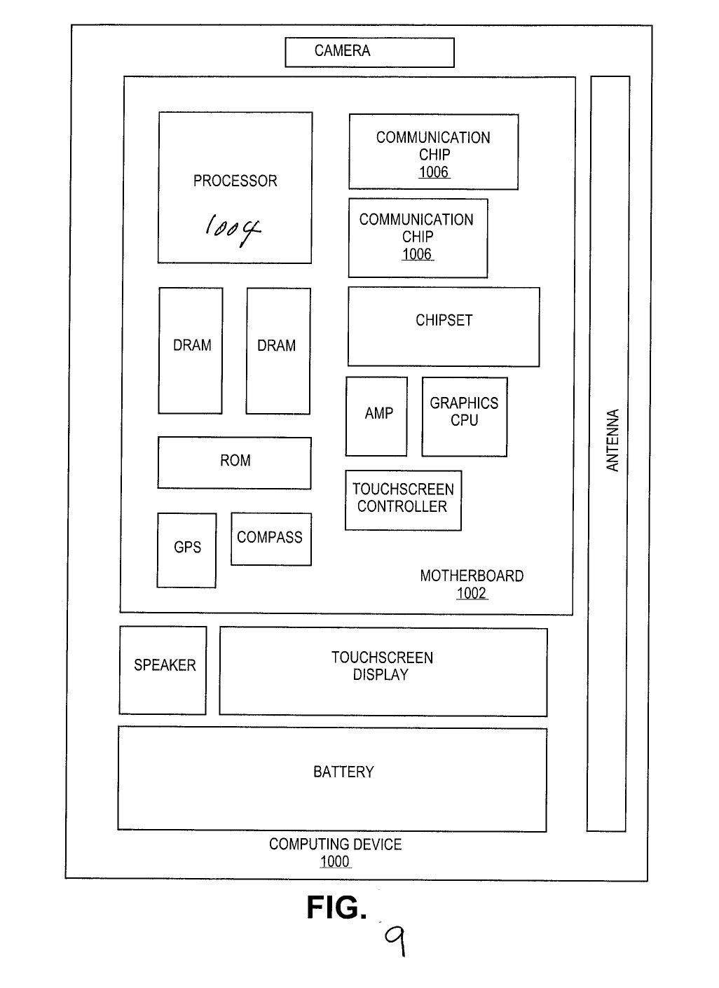

In FIG. 8, the devices 80 or 81 of FIG. 7 have been redrawn to show their connections in a memory array. The three memory elements of FIG. 8 each comprise two devices 80a, 81a; 80b, 81b; and 80c, 81c. The elements are coupled to their respective select transistors, specifically transistors 95, 96 and 97. Each of the elements is connected to a separate pair of bit lines BL1 and BL0. The differential programming of the devices with complementary data occurs in a manner to that described in conjunction with the memory element of FIG. 3. More specifically, the bit lines of the elements are held at a first potential for programming in one state and at a different potential for programming at another state. The current through the select transistor during programming flows in one direction for programming in one state and the other direction for programming in the other state. The select line also is at either V_{CC} or V_{SS} during programming as was the case for the programming shown in FIGS. 5A and 5B.

The reading of the state of the memory elements of FIG. 8 is the same as shown for FIGS. 6A and 6B. Again one bit line is at V_{CC} and the other at V_{SS}. The devices are effectively in series during reading since the sense lines are coupled to the high impedance inputs of a sense amplifiers.

FIG. 9 illustrates a computing device 1000 in accordance with one implementation of the invention. The computing device 1000 houses a board 1002. The board 1002 may include a number of components, including but not limited to a processor 1004 and at least one communication chip 1006. The processor 1004 is physically and electrically coupled to the board 1002. In some implementations the at least one communication chip 1006 is also physically and electrically coupled to the board 1002. In further implementations, the communication chip 1006 is part of the processor 1004.

Depending on its applications, computing device 1000 may include other components that may or may not be physically and electrically coupled to the board 1002. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1006 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing device 1000 includes an integrated circuit die packaged within the processor 1004. In some implementations of the invention, the integrated circuit die of the processor includes one or more memory elements that are formed in accordance with implementations of the invention. The term “processor” may refer to any device or portion of a device that processes electronic data from registers and/or memory to transform that electronic data into other electronic data that may be stored in registers and/or memory.

The communication chip 1006 also includes an integrated circuit die packaged within the communication chip 1006. In accordance with another implementation of the invention, the integrated circuit die of the communication chip includes one or more memory elements that are formed in accordance with implementations of the invention.

In further implementations, another component housed within the computing device 1000 may contain an integrated circuit die that includes one or more memory elements that are formed in accordance with implementations of the invention.

In various implementations, the computing device 1000 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1000 may be any other electronic device that processes data.

Thus, stacked MTJ devices forming memory elements which are differentially programmed with complementary data has been described. This structure provides a memory from which data may be more reliably read.

What is claimed is:

1. A magnetic memory element comprising:
two magnetic tunneling junction (MTJ) devices one stacked above the other, each having a pair of terminals;
a transistor, coupled to one terminal of each MTJ device; and
the other terminal of each MTJ device being coupled to a pair of bit lines.

2. The memory element of claim 1, wherein in the stacked MTJ devices, a free layer of one MTJ device faces a fixed layer in the other MTJ device.

3. The memory element of claim 1, wherein in the stacked MTJ devices, one of the fixed and free layers of one MTJ device faces a like layer in the other MTJ device.

4. The memory element of claim 1, wherein the one terminal of each of the MTJ devices form a common terminal.

5. The memory element of claim 1, wherein each of the MTJ devices comprise a plurality of aligned layers.

6. The memory element of claim 1, wherein potentials applied to the terminals of the MTJ devices, the transistor and the bit lines, differentially programs complementary data into the MTJ devices.

7. The memory element of claim 6, wherein the transistor is coupled to one of two potentials as a function of whether the memory element is to be programmed with a one or zero.

8. The memory element of claim 1, including a sense amp coupled to the transistor during reading of data from the element.

9. A memory comprising:
a plurality of elements, each having a pair of stacked magnetic tunneling junction (MTJ) devices;
a plurality of transistors, each transistor coupled to one of the elements, gates of the transistors being coupled to word lines and one terminal of each transistor being coupled to a sense line; and
pairs of bit lines, each element being coupled to a pair of bit lines.

10. The memory of claim 9 wherein the application of potentials on the word lines, sense lines and bit lines differentially programs each pair of MTJ devices of each of the elements.

11. The memory of claim 10, wherein during reading of data from the elements, sense lines are coupled to sense amps.

12. The memory of claim 11, wherein the sense amps are coupled to a reference potential which is compared to potential on the sense lines.

13. The memory of claim 12, wherein one stacked MTJ device of each element has a free layer facing a fixed layer in the other MTJ device of the element.

14. The memory of claim 13, wherein the layers of each MTJ device of each element are aligned.

15. The memory of claim 12, wherein one stacked MTJ device of each element has a free layer and a fixed layer, and wherein one of these layers faces a like layer in the other MTJ device of the element.

16. The memory of claim 15, wherein the layers of each MTJ device of each element are aligned.

17. A method of operating a magnetic memory comprising:
selectively coupling the word lines, sense lines, bit lines of memory elements each comprising a stacked pair of magnetic tunneling junction (MTJ) devices and a transistor to first potentials to differentially program the MTJ devices into first states;
selectively coupling the word lines, sense lines, bit lines of the memory elements to second potentials to differentially program the MTJ devices into second states; and
applying third potentials to the word lines and bit lines to detect the first and second states of the memory elements.

18. The method of claim 17, including coupling the sense lines of elements through the transistors to one terminal of sense amps.

19. The method of claim 17, including applying a reference potential to the other terminals of the sense amps.

20. The method of claim 19, wherein applying the third potentials to detect the first and second states includes applying one potential to one bit line and a second potential to the other bit line where the one potential and second potential are different potentials.
